(19) United States
(12) Patent Application Publication
(10) Pub. No.: US 2014/0183618 A1
(43) Pub. Date: Jul. 3, 2014

(54) SEMICONDUCTOR DEVICE

(71) Applicant: Eng Gek Hee, Sarawak (MY)

(72) Inventor: Eng Gek Hee, Sarawak (MY)

(73) Assignee: X-FAB SEMICONDUCTOR FOUNDRIES AG, Erfurt (DE)

(21) Appl. No.: 14/237,064

(22) PCT Filed: Aug. 5, 2011
(86) PCT No.: PCT/EP2011/063576

§ 371 Date: Feb. 20, 2014

(51) Int. Cl. H01L 29/78; H01L 29/792

(52) U.S. Cl. CPC H01L 29/7849; H01L 29/792
USPC 257/324; 257/348

(57) ABSTRACT

A semiconductor device comprising: at least one strained semiconductor layer to change the probability of an electron tunnelling from a first area to a second area.

### TECHNICAL FIELD

This invention relates to the field of semiconductor devices.

In one aspect, the present invention provides a semiconductor device comprising: at least one strained semiconductor layer to change the probability of an electron tunnelling from a first area to a second area.

### BACKGROUND

Strained silicon on insulator (SOI) structures may be used to improve the data retention in memory modules as well as to improve mobility gain in metal-oxide-semiconductor field-effect transistors (MOSFETs). The performance of a non-volatile memory (NVM), such as a flash memory, depends on the device's ability to control the trapping and releasing of electrons within a gate. The gate is isolated from the surrounding structures and the isolation forms a barrier to the electrons. In a reliable flash memory, the electrons may be trapped within the barriers for years. The performance of a memory is limited by a small probability that the electrons escape through the barriers by tunneling. The underlying physical mechanism which contributes to a better performance of a strained semiconductor substrate is a reduction of the probability that an electron tunnels through barriers provided within a semiconductor structure.

The tunneling probability may be expressed by the following equation (equation 1).

$$T \approx exp ( - \frac{4 \sqrt{2 {m}^{*}} {E}_{g}^{3 / 2}}{3 e ℏ ℰ} ) \qquad Eq . 1 )$$

In equation 1, T is the tunneling probability, E_{g} is the bandgap of the semiconductor, m* is the reduced mass of the electron-hole system, also called electron conductivity mass or effective mass, ε is the electric field, e is the charge of the electrons and is the Planck constant. The tunneling probability may be reduced by manipulating the different factors in this equation.

### BRIEF SUMMARY

The inventor has appreciated that strained substrates can be used in a memory device to improve the reliability of the memory.

### BRIEF DESCRIPTION OF THE DRAWINGS

Some preferred embodiments of the invention will now be described by way of example only and with reference to the accompanying drawings, in which:

FIG. 1 is an illustration of the energy levels of a semiconductor device according to an embodiment of the present invention.

FIG. 2 is a vertical cross-section of a semiconductor device with a strained-Si layer according to an embodiment of the present invention.

In accordance with embodiments of the invention, a strained substrate may reduce the probability that an electron tunnels through a barrier in the following two ways.

First, the height of the tunnel oxide barrier may be increased by the use of tensile stress strained substrates. For example, the strain would reduce tunnel leakage currents by increasing the barrier height between a SiO₂ layer and a Si layer via strain-induced changes in the Si and SiO₂ electron affinity. For nitride-based memories, the primary electron loss mechanism at elevated temperatures is the thermal de-trapping of the stored electrons, whereby the thermal energy is large enough to overcome the height of the barrier. The thermal electron de-trapping is proportional to exp(−Ea/kT), where Ea is the electron trap activation energy. Tensile stress strain may alter the value of Ea in oxy-nitride, thereby creating a deeper trap and thus improving the Data Retention reliability of the nitride-based memory.

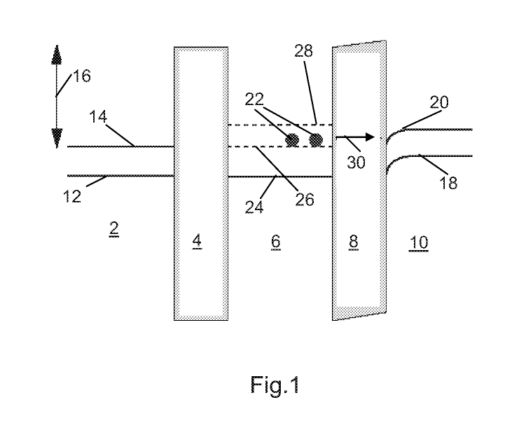

Second, the value of the total electron conductivity mass m* may be increased by the strain, thereby decreasing the tunneling probability according to equation 1. FIG. 1 shows the energy level structure of a memory device. From left to right, FIG. 1 shows an N-type control gate (2), an SiO₂ layer (4), an N-type floating gate (6), a second SiO₂ layer (8) and a P-type silicon substrate (10). The N-type control gate (2) has two electronic energy eigenstates (12 and 14). The height of the energy barrier provided by the SiO₂ layer (4) is around 9 eV. The difference in energy (indicated by arrow 16) between the SiO₂ layer (4) and the highest energy level of the N-type control gate (2) is around 3.2 eV. The P-type silicon substrate (10) has two energy levels (18 and 20). The N-type floating gate (6) is the place where electrons (22) are stored, thereby forming a memory. The N-type floating gate (6) has a lowest energy level (24) and two higher energy levels (26 and 28), which higher energy levels are created when strain is applied to the gate (6).

The n-type floating gate (6) shown in FIG. 1 is bounded by SiO₂ barriers (4, 8) and electrons (22) may be trapped in the floating gate. The tensile stress causes a splitting of the conduction band and two energy levels (26, 28) within the floating gate are created, which are referred to herein as EΔ2 and EΔ4, respectively. The lower level EΔ2 will be more likely to be populated by the trapped electrons than the higher energy level EΔ4. The electron conductivity mass of energy level EΔ2 is 0.98 times the free electron mass, while the electron conductivity mass of energy level EΔ4 is 0.19 times the free electron mass. A larger electron conductivity mass corresponds to a smaller value of the tunneling probability in accordance with Eq. 1. The tunneling current (30) in these states is significantly reduced due to the change in conductivity mass when compared to the conductivity mass in an unstrained lattice.

For unstressed bulk Si, the conduction band comprises six degenerate valleys. The degeneracy reflects the cubic symmetry of the Si lattice. The effective mass for any direction is inversely proportional to the curvature of the energy dispersion relationship in that direction. Consequently, the effective mass of each ellipsoid is anisotropic, with the transverse mass (perpendicular to the axis) given by mₜ=0.19 m₀ being significantly smaller than the longitudinal mass (parallel to the axis) given by mₜ=0.98 m₀, where m₀ is the free electron mass. The total electron conductivity mass m* is obtained by adding the contributions of the six degenerate valleys and is given by equation 2.

$${m}^{*} = {[ \frac{1}{6} ( \frac{2}{{m}_{i}} ) + ( \frac{4}{{m}_{t}} ) ]}^{- 1} \qquad ( Eq . 2 )$$

Where mₜ=0.19 m₀ & mᵢ=0.98 m₀. Equation 2 expressed in terms of the free electron mass is m*=0.047 m₀, which is much smaller than the electron conductivity mass in the split lower energy level 26 and corresponds to a much larger tunneling probability.

A different way of understanding the stress induced change of the electron conductivity mass is by considering the change in shape of the atomic lattice of the semiconductor material due to stress. The electron conductivity mass is dependent on the direction in which an electron travels through a lattice. While bulk stress-free silicon has a lattice structure with cubic symmetry, a silicon crystal under stress does not have the same symmetry and an electron travelling through the stressed lattice will have a different conductivity mass.

The splitting resulting in level 26 also increases the SiO₂/Si barrier height, which will also decrease the tunneling current.

A way to implement the use of tensile strain in a memory is by selecting SiGe-free strained silicon-on-insulator (SSOI). The selection of SiGe-free SSOI instead of a strained-Si/SiGe-on-insulator substrate prevents out-diffusion of germanium. The out-diffusion of germanium decreases the value of E_{g} in equation 1, thereby increasing the tunneling probability and decreasing the data retention reliability of the NVM.

A benefit of using SiGe-free strained SOI, apart from the ability to avoid the problem of Germanium out-diffusion, is that it can also avoid the problem of coarse nano-topography, both of which are associated with a high thermal budget process in direct oxidation of SiGe during the fabrication process. The use of a Silicon Germanium-on-insulator (SGOI) substrate will lead to Ge Out-diffusion during the high thermal process used for device fabrication. In order to eliminate such problem, Strained Silicon-on-Insulator (SSOI) is used instead of SGOI.

The use of fully depleted SOI technology may be beneficial for the formation of 20-50 nm thick strained-Si substrates using SiGe-free SSOI. Fully-depleted type SOI devices have the advantage that short channel effects and floating body effects due to charge pile-up are suppressed. The use of fully-depleted strained silicon-on-insulator (FD-SSOI) to form a 20 to 50 nm thin film of Si enables the implementation of the strained-Si concept for SONOS and CMOS devices. FD-SSOI may also increase the electron and hole mobility in both n-and p-strained-SOI MOSFET for channel, gate and source-drain regions, depending on the tensile/compressive stress axis (biaxial or uniaxial).

As mentioned above, a benefit of a fully-depleted type SOI device is that the short channel effect and floating body effect due to charge pile-up are suppressed. The floating-body effect is an electrical anomaly usually seen in Partially-Depleted devices. Such floating-body effect problem could be solved either by providing a body contact for the device or, as proposed herein, by using the fully depleted device concept to suppress the effect.

The fully depleted SOI device technology may be combined with Deep Trench Isolation (DTI). DTI has an advantage of better NVM reliability and better packing density. The device also offers better NVM integration possibilities by utilising SOI technology.

In particular, the device may be a nanoscale n-channel nitride based semiconductor-oxide-nitride-oxide-semiconductor (SONOS) non-volatile memory with DTI on a fully depleted strained silicon-on-insulator (FD-SSOI) substrate. The device may use SOI based complementary metal oxide semiconductor (CMOS) technology. The use of a strain engineering approach based on state of art semiconductor technology achieves better NVM reliability in terms of data retention. Better reliability is achieved by process induced tensile stress, which may lead to stress-altered changes in the SiO₂/Si barrier height and changes in the trap activation energy in nitride trap based memories. The FD-SSOI use for SONOS and CMOS devices increases the electron and hole mobility in both an n-and a p-strained-SOI MOSFET.

A DTI module built on a SOI substrate enables a very good isolation from the bulk Si with lower parasitic capacitance together with very good isolation of the n- and p-well structures, which reduces power consumption and crosstalk between the n- and p-well structures. The latch-up free benefit of a DTI design provides the possibility of better circuit packing density resulting in improved scalability. The implementation of the DTI concept between memory array blocks enables reduction of the entire macro block standby leakage (off-state leakage). Higher device density is achievable by simplification of the lateral and vertical isolation structures and therefore circuit packing density could be increased, specifically in a periphery circuit for a NVM macro block.

The combination of the features and techniques discussed above enables the fabrication of a low power consumption portable microelectronics memory device. A “SONOS NVM macro” may be constructed with the architecture of SONOS Gate channels with tensile stress on a SiGe-free fully depleted SOI substrate, isolated by DTI technology. This SONOS NVM macro is suitable for applications in high-energy radiation environments, because of better radiation hardness properties which reduce the memory soft error rate. Advantages are lower parasitic capacitance, latch-up free architecture and higher circuit packing density. Furthermore, a memory array's soft error rate or data corruption caused by cosmic rays and natural radioactive background signals is suppressed by this arrangement.

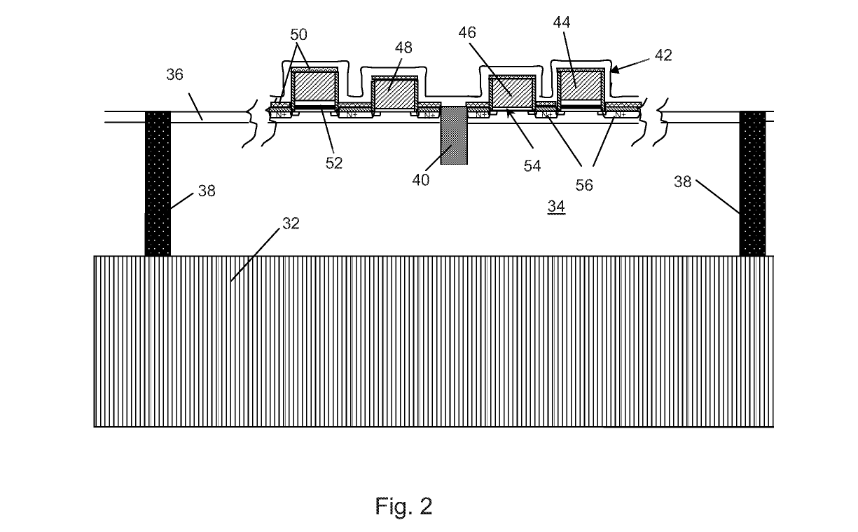

An embodiment of the present invention is illustrated in FIG. 2 and described as follows. First, the structure is described and then the manufacturing process is described.

An example of a semiconductor device obtained by the process briefly outlined above is shown in FIG. 2. A handle wafer (32) is provided with a substantially flat top surface. On the top surface of the handle wafer (32), a layer of SiO₂ (34) is provided with a thickness of approximately 1 micrometer. On top of the SiO₂ layer (34) a strained Si layer (36) is provided with a thickness of about 20 to 50 nanometers. One or more DTI layers (38) are provided, extending from the top of the strained Si layer (36) to the handle wafer (32), thereby isolating all semiconductor layers formed on top of the handle wafer (32) on one side of a DTI (38) from those on the other side of the DTI (38). A tensile STI (40) is provided, which extends from a top layer into the SiO₂ (34) layer, but not up to the handle wafer (32).

On top of the strained Si layer (36) and partially embedded in the Si layer (36) gates are formed. Examples are shown as a SONOS gate (44) and an access gate (46). The material of the gates themselves is poly-Si (48) and the gates as well as the surfaces between the gates are covered by Ni-silicide (50). A high stress nitride film (42) is provided over the Ni-silicide layer (50). Between the Poly-Si (48) of the gates and the strained Si layer (36) gate oxide (GOX) layers (54) and oxy-nitride layers (52) are provided. The gates are connected by an n+ doped semiconductor material (56).

The device shown in FIG. 2 illustrates how to create a strain condition over a fully depleted n-channel SONOS gate and an access gate or select gate using SiGe-Free SSOI with DTI for an NVM array. Conventional semiconductor fabrication methods are used to obtain a high packing density NVM cell using strain engineering, making the device fully compatible with nanoscale CMOS processes.

A pad oxide is formed on a ready made SiGe-Free SSOI wafer substrate, and a SiN layer is deposited on the substrate. An active area is then defined by a masking step. An active area isolation is formed by anisotropic etching of the SiN layer, pad oxide and a certain depth of the wafer substrate, thereby forming shallow trench isolation (STI) structures (40); followed by another lithography mask to define deeper DTI regions (38). The DTI regions extend from the surface of the device to the buried oxide interface (32) of the handle wafer. The STI trenches and DTI trenches are processed through liner oxidation prior to being filled with tensile silicon oxide HDP insulating material, followed by thicker DTI LPTEOS (which is low pressure chemical vapour deposition using tetraethyl orthosilicate as raw material) insulating material. Chemical and mechanical polishing is used to polish away unwanted silicon oxides above the SiN layer covering the active area. Subsequently, the SiN layer and pad oxide are removed. The active area, STI and DTI isolation are now formed.

A sacrificial thermal oxide layer is then grown followed by various SONOS cell formation masks, including a SONOS well implantation mask, nitride deposition, a SONOS Channel Implantation mask for SONOS threshold voltage optimization, cleaning steps, nitride and sacrificial thermal oxide removal steps and a prior proprietary ONO oxidation process. Subsequently, the next steps comprise masking for ONO removal of the non-SONOS area and finally a silicon re-oxidation step by rapid thermal oxidation. The I/O transistors and access gate and/or select gate transistor wells are formed with various implantation masking and cleaning steps as in conventional CMOS logic processes.

The sacrificial oxide layer and nitride layer (on the SONOS area only) are then removed by wet cleaning using buffer HF (hydrogen fluoride) dipping and hot acid phosphoric stripping respectively and then a first thermal gate oxide is grown. For a dual oxide process, with a first oxide region having a first oxide thickness, and a second oxide region having a second oxide thickness, a dual gate mask is used to cover the envisaged first oxide region. This first gate oxide is removed from the second oxide region by wet cleaning, and the mask is removed. A second thermal gate oxide is now grown to define the final gate oxide thickness in the first and second oxide regions. The gate oxides are grown by furnace oxidation.

After gate poly-silicon has been deposited, all the transistors are then defined by a poly mask over the active region, and unwanted polysilicon in the area not covered by the mask is etched by anisotropic etching. This is followed by various masking, LDD implantations and cleaning steps. An L-shape poly-Si sidewall is now formed, followed by source/drain implantations, Ni-salicidation and metallization using nanoscale semiconductor fabrication methods.

The required SONOS cell transistors, I/O transistors and access gate (46) or select gate transistors are then fabricated.

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. A semiconductor device comprising:
at least one strained semiconductor layer to reduce the probability of an electron tunnelling from a first area to a second area.

2. A semiconductor device according to claim 1, further comprising a substrate having an insulator layer disposed thereon.

3. A semiconductor device according to claim 2, further comprising a silicon layer disposed on the insulator layer wherein the silicon layer is strained.

4. A semiconductor device according to claim 3, further comprising a deep trench isolation module provided within the silicon on insulator layer and insulator layer.

5. A semiconductor device according to claim 3 or II, further comprising one or more gates on the strained silicon layer.

6. A semiconductor device according to claim 4, wherein the deep trench isolation module extends to the substrate.

7. A semiconductor device according to claim 3, wherein the silicon on insulator layer is substantially fully depleted.

8. A semiconductor device according to claim 7, wherein the fully depleted strained silicon on insulator layer is 20 to 50 nm thick.

9. A semiconductor device according to claim 3, wherein the silicon on insulator layer is substantially SiGe-free.

10. A semiconductor device according to claim 3 wherein the silicon layer is an n-strained SOI.

11. A semiconductor device according to claim 3, wherein the silicon layer is a p-strained SOI.

12. A semiconductor device according to claim 3, wherein there is provided an access gate or select gate on the strained silicon layer.

13. A semiconductor device according to claim 3, wherein there is provided a SONOS gate on the strained silicon layer.

14. A semiconductor device according to claim 12, wherein a high stress film is provided over the SONOS gate and/or access/select gate.

15. A semiconductor device according to claim 1, wherein the device comprises a SONOS device.

16. A semiconductor device according to claim 1, wherein the device comprises a CMOS device.

17. A semiconductor device according to claim 1, wherein the device is a MOSFET.
